(19) United States
(12) Patent Application Publication
(10) Pub. No.: US 2025/0115256 A1
(43) Pub. Date: Apr. 10, 2025

(54) Method For Generating a Data Set

(71) Applicant: Robert Bosch GmbH, Stuttgart-Feuerbach (DE)

(72) Inventors: Dr. Stefan Nordbruch, Leonberg (DE); Manfred Harrer, Gumpoldskirchen (AT)

(73) Assignee: Robert Bosch GmbH, Stuttgart-Feuerbach (DE)

(21) Appl. No.: 18/961,775

(22) Filed: Nov. 27, 2024

Related U.S. Application Data
(63) Continuation of application No. PCT/EP2023/064594, filed on May 31, 2023.

(30) Foreign Application Priority Data
May 31, 2022 (DE) 10 2022 113 744.9

(51) Int. Cl. B60W 50/00; B60W 60/00

(52) U.S. Cl. CPC B60W 50/0098; B60W 60/00; B60W 2552/00

(57) ABSTRACT

A method includes receiving a motor-vehicle-generated environmental data that represent an environment of a motor vehicle from a perspective of the motor vehicle, receiving an infrastructure-generated environmental data that represent the environment of the motor vehicle from a perspective of an infrastructure, and editing the motor-vehicle-generated environmental data based on the infrastructure-generated environmental data in order to ascertain an edited motor-vehicle-generated environmental data. The method includes generating a data set that comprises the edited motor-vehicle-generated environmental data.

### CROSS-REFERENCE TO RELATED APPLICATIONS

This application is a continuation of PCT International Application No. PCT/EP2023/064594, filed on May 31, 2023, which claims priority under 35 U.S.C. § 119 to German Patent Application DE 10 2022 113 744.9, filed on May 31, 2022.

### FIELD OF THE INVENTION

The invention relates to a method for generating a data set, to a method for testing at least one component of a process chain for an at least partially automated driving function of a motor vehicle, to a method for generating at least one part of an algorithm for an at least partially automated driving function of a motor vehicle, to a device, to a computer program and to a machine-readable storage medium.

### BACKGROUND

German Patent Application DE 10 2013 001 326 A1 discloses a motorcar that has been designed to exchange operating data with a traffic object located in a neighborhood of the motorcar and, by this exchange, to coordinate a driving maneuver of the motorcar with the traffic object.

For the purpose of testing an algorithm for performing an at least partially automated driving function of a motor vehicle, use is made of motor-vehicle-generated environmental data. A motor vehicle captures its environment during its journey with the aid of environment sensors and makes environmental data corresponding to the capture available. These environmental data can be used to test an algorithm for performing an at least partially automated driving function of a motor vehicle.

### SUMMARY

A method includes receiving a motor-vehicle-generated environmental data that represent an environment of a motor vehicle from a perspective of the motor vehicle, receiving an infrastructure-generated environmental data that represent the environment of the motor vehicle from a perspective of an infrastructure, and editing the motor-vehicle-generated environmental data based on the infrastructure-generated environmental data in order to ascertain an edited motor-vehicle-generated environmental data. The method includes generating a data set that comprises the edited motor-vehicle-generated environmental data.

### BRIEF DESCRIPTION OF THE DRAWINGS

Exemplary embodiments of the invention are represented in the drawings and will be elucidated in more detail in the following description.

FIG. 1 shows a flowchart of a method according to a first aspect;

FIG. 2 shows a flowchart of a method according to a second aspect;

FIG. 3 shows a flowchart of a method according to a third aspect;

FIG. 4 shows a schematic diagram of a motor vehicle in the course of a journey through an infrastructure;

FIG. 5 shows a device according to a fourth aspect; and

FIG. 6 shows a computer-readable storage medium according to a sixth aspect.

### DETAILED DESCRIPTION OF THE EMBODIMENT(S)

The present disclosure is based upon and includes the insight that a data set is generated that comprises edited motor-vehicle-generated environmental data, these environmental data describing or representing an environment of a motor vehicle from the perspective of the motor vehicle. Accordingly, motor-vehicle-generated environmental data are edited, the editing being carried out on the basis of infrastructure-generated environmental data that represent the environment of the motor vehicle from the perspective of an infrastructure.

Consequently, information that the motor vehicle itself does not have is available for the editing of the motor-vehicle-generated environmental data. Environment sensorics of the motor vehicle, with the aid of which the environment of the motor vehicle was captured in order to generate the motor-vehicle-generated environmental data, have a limited range in order to capture the environment. Objects in the environment of the motor vehicle may also conceal—that is to say, shield—further objects in the environment of the motor vehicle from the environment sensorics, so that the environment sensorics of the motor vehicle cannot capture such further objects.

In contrast, infrastructure environment sensorics are better able to capture such other objects. Infrastructure environment sensorics may also have a greater range than the environment sensorics of the motor vehicle, so more of the environment of the motor vehicle can be captured by the infrastructure environment sensorics than by the environment sensorics of the motor vehicle itself.

Consequently, the motor-vehicle-generated environmental data can be edited efficiently, so that edited motor-vehicle-generated environmental data can be made available in the form of the data set. On the basis of such a data set, at least one component of a process chain for an at least partially automated driving function of a motor vehicle can then be tested in advantageous and efficient manner, and/or at least one part of an algorithm for an at least partially automated driving function of a motor vehicle can be generated.

The approach described herein is to be seen in contrast to the prior art described in the foregoing, according to which only motor-vehicle-generated environmental data as such-that is to say, non-edited environmental data—were used for the testing of an algorithm for an at least partially automated driving function of a motor vehicle. According to the prior art, only the environment such as presents itself from the perspective of the motor vehicle, but not from the perspective of an infrastructure, was used for the testing of such an algorithm.

For example, such an algorithm or a component of a process chain for an at least partially automated driving function of a motor vehicle based solely on non-edited motor-vehicle-generated environmental data would be developed further for a long time and at great expense, even though an appropriately minor hardware modification in respect of an environment sensor of the motor vehicle—for instance, 1° more field of view or 20 m more range for the environment sensor—is a better solution for the future. Since, according to the concept described herein, the motor-vehicle-generated environmental data are edited on the basis of the infrastructure-generated environmental data, questions such as whether, for instance, an appropriately minor hardware modification is not the better solution can be answered efficiently.

The concept described herein accordingly encompasses generating a data set that comprises edited motor-vehicle-generated environmental data. This means that the motor-vehicle-generated environmental data are edited. This is to be seen, in particular, in contrast to a fusion of motor-vehicle-generated environmental data and infrastructure-generated environmental data. This is because in the case of a data fusion a completely new data set arises: the merged data set.

By the wording “edited,” on the other hand, it is, in particular, made clear that the original data set—that is to say, the motor-vehicle-generated environmental data—is still recognizable or existent. This means, in particular, that the original motor-vehicle-generated environmental data are still recognizable or existent in the edited motor-vehicle-generated environmental data.

This is to be regarded as analogous to a treatment of water or to a renovation of a piece of furniture. After the renovation, the original piece of furniture can still be recognized or—to be more precise—is still present. Where appropriate, the corners of the piece of furniture have been rounded off, or the piece of furniture has been polished within the scope of the renovation. But a completely new piece of furniture does not arise. The same applies to treated water. In this case, for instance, substances are filtered out, so the original water is still existent and recognizable, and no new water is produced.

Consequently, it is clear that a data fusion is not an editing of motor-vehicle-generated environmental data. Consequently, editing in the sense of the description is, in particular, different from data fusion—that is to say, from a merging of data. Edited motor-vehicle-generated environmental data are consequently, in particular, not merged environmental data—that is to say, they do not correspond, in particular, to merged environmental data.

In one embodiment of the method according to the first aspect, the invention provides that the editing includes validating the motor-vehicle-generated environmental data in order to ascertain a result of validation, so that the edited motor-vehicle-generated environmental data include the result of validation.

As a result of this, the technical advantage is brought about, for example, that the motor-vehicle-generated environmental data can be edited efficiently. Validating may be, for example, a checking of dimensions of an object that is detected in the environment of the motor vehicle on the basis of the motor-vehicle-generated environmental data. The motor vehicle is moving, in some cases, very dynamically (speed) in an unknown world. The infrastructure is stationary and is known to a partial known world (all stationary objects, the properties, positions, etc. thereof). These objects are accordingly defined as correct—that is to say, as a reference. With the “correct” data—that is to say, with the reference—of the infrastructure (the “ground truth”), the captured and ascertained data of the motor vehicle can be checked for “correctness”—that is to say, validated.

In one embodiment of the method according to the first aspect, the invention provides that the editing includes a checking of the plausibility of the motor-vehicle-generated environmental data in order to ascertain a result of the checking of plausibility, so that the edited motor-vehicle-generated environmental data include the result of the checking of plausibility.

As a result of this, the technical advantage is brought about, for example, that the motor-vehicle-generated environmental data can be edited efficiently. Validating may include, for example, a test for plausibility. Validating may include, for example, a step of checking whether information that is ascertained from the motor-vehicle-generated environmental data precisely matches information that is ascertained from the infrastructure-generated environmental data. A checking of plausibility may, for example, include a step of checking whether information that is ascertained from the motor-vehicle-generated environmental data matches, within a tolerance range, information that is ascertained from the infrastructure-generated environmental data.

In one embodiment of the method according to the first aspect, the invention provides that the editing includes purging the motor-vehicle-generated environmental data of faulty data, so that the edited motor-vehicle-generated environmental data comprise purged motor-vehicle-generated environmental data.

As a result of this, the technical advantage is brought about, for example, that the motor-vehicle-generated environmental data can be edited efficiently. An error or a problem may be, for example, the fact that an environment sensor of the motor vehicle is soiled, and, as a result, correspondingly faulty environment-sensor data are present in the motor-vehicle-generated environmental data. These data errors can be found and removed by a comparison with the environmental data of the infrastructure, and can be replaced, for instance, with the correct environmental data of the infrastructure. One advantage is, for example, that the motor-vehicle-generated environmental data may still be usable.

The purging accordingly includes, in particular, removing the faulty data and, in particular, replacing the faulty data with correct environmental data of the infrastructure (infrastructure-generated environmental data).

In one embodiment of the method according to the first aspect, the invention provides that the editing includes analyzing the infrastructure-generated environmental data in order to obtain environmental information concerning the environment of the motor vehicle, the editing further including enriching the motor-vehicle-generated environmental data with the environmental information, so that the edited motor-vehicle-generated environmental data include the environmental information.

As a result of this, the technical advantage is brought about, for example, that the motor-vehicle-generated environmental data can be edited efficiently. The environmental data of the infrastructure also include, for example, data from regions in the environment that the motor vehicle cannot capture with the aid of its environment sensorics, for example because the region(s) is/are not within the visual range of the environment sensors, and/or there are masking phenomena in the scene, for instance because a pedestrian is standing behind a bicycle or a cyclist. The non-captured region(s) can be added as environmental information to the motor-vehicle-generated environmental data in order to enrich the latter.

In one embodiment of the method according to the first aspect, the invention provides that the infrastructure-generated environmental data include context data that represent a context of the environment, so that the motor-vehicle-generated environmental data are edited on the basis of the context data. As a result of this, the technical advantage is brought about, for example, that the motor-vehicle-generated environmental data can be edited efficiently.

On the basis solely of the motor-vehicle-generated environmental data prior to the editing thereof, the context in which the motor vehicle has found itself during its journey is not usually apparent. For example, a certain behavior of traffic in the environment of the motor vehicle makes sense only when the context is known. If, for example, all the motor vehicles in the environment of the motor vehicle stop or drive along the left or right edge of the road, this is rather unusual behavior without knowledge of the context. But, to the extent that the context is known, for example that emergency services with blue lights were in transit at that time, such a behavior makes sense, because motor vehicles have to clear a path for emergency services with blue lights that are in transit.

In one embodiment of the method according to the first aspect, the invention provides that the context comprises one or more of the following contexts: constructional context, traffic context, event context, weather context, road-condition context. As a result of this, the technical advantage is brought about, for example, that the motor-vehicle-generated environmental data can be edited efficiently.

A constructional context indicates, for example, whether there was a construction site in the environment of the motor vehicle.

A traffic context indicates, for example, how a traffic-signal system has switched—that is to say, for example, which signal indication obtained—and/or whether there was a traffic diversion, for example regulated by a traffic sign, and/or whether there was a change in a speed-limit.

An event context indicates, for example, whether an emergency-services vehicle that is on an assignment is located in the environment of the motor vehicle.

A weather context indicates, for example, weather in the environment of the motor vehicle.

A road-condition context indicates, for example, whether there are one or more holes in the road, whether the road is icing up, and/or whether the road is wet.

In one embodiment of the method, the invention provides that the motor-vehicle-generated environmental data were generated on the basis of a capture of the environment with the aid of environment sensorics of the motor vehicle, in which connection at least one technical parameter, in particular range and/or field of view, of the environment sensorics of the motor vehicle is received, the data set being generated in such a manner that the data set includes the at least one technical parameter of the environment sensorics of the motor vehicle.

As a result of this, the technical advantage is brought about, for example, that the data set concerning the edited motor-vehicle-generated environmental data contains additional information that can be used, for example, in advantageous manner for testing at least one component of a process chain for an at least partially automated driving function of a motor vehicle, and/or for generating at least one part of an algorithm for an at least partially automated driving function of a motor vehicle.

In one embodiment of the method according to the first aspect, the invention provides that the infrastructure-generated environmental data were generated on the basis of a capture of the environment with the aid of environment sensorics of the infrastructure, in which connection infrastructure environment-sensorics data are received that specify at least one technical parameter of the environment sensorics of the infrastructure, the data set being generated in such a manner that the data set includes the at least one technical parameter of the environment sensorics of the infrastructure.

As a result of this, the technical advantage is brought about, for example, that the data set concerning the edited motor-vehicle-generated environmental data contains additional information that can be used, for example, in advantageous manner for testing at least one component of a process chain for an at least partially automated driving function of a motor vehicle, and/or for generating at least one part of an algorithm for an at least partially automated driving function of a motor vehicle.

In one embodiment of the method according to the first aspect, the invention provides that the motor-vehicle-generated environmental data represent a respective environment of several motor vehicles from the perspective of the respective motor vehicle in the course of a respective journey through a respective infrastructure region of the infrastructure, the infrastructure-generated environmental data representing the respective environment of the motor vehicles from the perspective of the infrastructure.

As a result of this, the technical advantage is brought about, for example, that motor-vehicle-generated environmental data from several motor vehicles are available for generating the data set. Consequently, a data set can be generated that is particularly suitable in advantageous manner for use for a method according to the second aspect and/or according to the third aspect.

In one embodiment of the method according to the first aspect, the invention provides that the respective infrastructure region is, in each instance, an element selected from the following group of infrastructure regions: road interchange, construction site, tunnel, freeway entrance ramp, freeway exit ramp, freeway, stopping-point, entry, exit, constriction, road constriction, lane constriction, underpass, place with adjacent public traffic, in particular football stadium or railroad station.

As a result of this, the technical advantage is brought about, for example, that particularly important infrastructure regions as regards testing at least one component of a process chain for an at least partially automated driving function of a motor vehicle and/or for generating at least one part of an algorithm for an at least partially automated driving function of a motor vehicle are taken into consideration.

A road interchange is, for example, an intersection, a junction, a T-intersection, a roundabout or a freeway intersection.

In one embodiment of the method according to the first aspect, the invention provides that at least some of the respective infrastructure regions are identical to one another, where “identical” means that it is a question of a like type of infrastructure region and a question of the same infrastructure region, and/or where at least some of the infrastructure regions are different from one another, where “different” means that, although it may be a question of a like type of infrastructure region, it may be a question of different infrastructure regions, or that it may be a question of differing types of infrastructure region.

As a result of this, the technical advantage is brought about, for example, that use may be made of motor-vehicle-generated environmental data from an identical infrastructure region and/or from different infrastructure regions.

In one embodiment of the method according to the first aspect, the invention provides that the data set is generated in such a manner that this data set comprises the motor-vehicle-generated environmental data and/or the infrastructure-generated environmental data.

As a result of this, the technical advantage is brought about, for example, that the data set is generated efficiently. According to this embodiment, the invention accordingly provides that the data set comprises not only the edited motor-vehicle-generated environmental data but, additionally, the non-edited motor-vehicle-generated environmental data and/or the infrastructure-generated environmental data that are used for the editing of the motor-vehicle-generated environmental data.

Consequently, a data set is available in advantageous manner that is particularly suitable to be used for the method according to the second aspect and/or for the method according to the third aspect.

In one embodiment of the method according to the second aspect, the invention provides that the at least one component includes an algorithm for performing the at least partially automated driving function, the testing including simulating a motor vehicle that is traveling in at least partially automated manner on the basis of the at least partially automated driving function, executing the algorithm.

As a result of this, the technical advantage is brought about, for example, that an algorithm for performing the at least partially automated driving function can be tested efficiently.

In one embodiment of the method according to the second aspect, the invention provides that the motor-vehicle-generated environmental data were generated on the basis of a capture of the environment with the aid of environment sensorics of the motor vehicle, in which connection the data set includes at least one technical parameter—in particular, range and/or field of view—of the environment sensorics of the motor vehicle, the at least one component including environment sensorics of the motor vehicle, the testing including changing the at least one technical parameter on the basis of the data set, in order to obtain at least one changed technical parameter, and the testing including simulating a motor vehicle, exhibiting simulated environment sensorics with the at least one changed technical parameter, that is traveling in at least partially automated manner on the basis of the at least partially automated driving function, using the simulated environment sensorics.

As a result of this, the technical advantage is brought about, for example, that the environment sensorics of the motor vehicle can be tested efficiently. In particular, it can be tested in an advantageous manner whether the changed technical parameter brings about an improvement. For example, it can be tested whether somewhat more field of view and/or more range are/is sufficient in order that the motor vehicle travels more efficiently in at least partially automated manner, using its environment sensorics. For example, an algorithm for an at least partially automated driving function does not have to be developed further for a long time and in costly manner if such a small technical change in the environment sensorics of the motor vehicle brings about a similar result. An application in which the motor vehicle has not traveled sufficiently well in at least partially automated manner, so that an algorithm would have to be improved accordingly, but where, in this concrete application, it is not the algorithm that is at fault, but rather inadequate environment sensorics, may be, for example, the fact that a pedestrian enters late into the visual range of the environment sensorics of the motor vehicle by reason of an insufficient range and/or an insufficient field of view, so that the motor vehicle brakes late. An increase in the range and/or in the field of view can mitigate such a situation without an algorithm having to be developed further in protracted manner.

In one embodiment of the method according to the third aspect, the invention provides that the at least one part of the algorithm is generated by using an artificial neural network. As a result of this, the technical advantage is brought about, for example, that the at least one part of the algorithm can be generated efficiently.

According to one embodiment of the method according to the second aspect and/or according to the third aspect, the invention provides that the data set comprises the motor-vehicle-generated environmental data and/or the infrastructure-generated environmental data. As a result of this, the technical advantage is brought about, for example, that use can be made of a particularly suitable data set.

In one embodiment of the method according to the second aspect and/or according to the third aspect, the invention provides that the data set was generated in accordance with the method according to the first aspect. As a result of this, the technical advantage is brought about, for example, that use is made of a particularly suitable data set.

Remarks that have been made in connection with the method according to the first aspect and/or according to the second aspect apply analogously to the method according to the third aspect, and conversely. Technical functionalities and features of the method according to the first aspect and/or according to the second aspect result analogously from corresponding technical functionalities and features from the method according to the third aspect, and conversely.

The embodiments described herein can be combined with one another in arbitrary manner, even if this has not been described explicitly. This means, in particular, that features from embodiments of the method according to the first aspect can be used in embodiments of the method according to the second aspect and/or according to the third aspect, and conversely. Furthermore, device features arise out of corresponding method features, and conversely.

In one embodiment of the method according to the first aspect and/or according to the second aspect and/or according to the third aspect, the respective method is a computer-implemented method.

An at least partially automated driving function brings about an at least partially automated driving of the motor vehicle.

The wording “at least partially automated driving” encompasses one or more of the following cases: assisted driving, partially automated driving, highly automated driving, fully automated driving. The wording “at least partially automated” accordingly encompasses one or more of the following wordings: assisted, partially automated, highly automated, fully automated.

“Assisted driving” means that a driver of the motor vehicle permanently performs either the lateral guidance or the longitudinal guidance of the motor vehicle. The respective other driving task (that is to say, controlling the longitudinal guidance or the lateral guidance of the motor vehicle) is carried out automatically. This accordingly means that in the case of assisted driving of the motor vehicle either the lateral guidance or the longitudinal guidance is controlled automatically.

“Partially automated driving” means that longitudinal guidance and lateral guidance of the motor vehicle are controlled automatically in a specific situation (for example: driving on a freeway, driving within a parking lot, overtaking an object, driving within a lane that is defined by lane markings) and/or for a certain period of time. A driver of the motor vehicle does not have to control the longitudinal guidance and lateral guidance of the motor vehicle himself/herself manually. But the driver has to monitor the automatic control of the longitudinal guidance and lateral guidance permanently, in order to be able to intervene manually if necessary. The driver has to be prepared to take over the guidance of the motor vehicle completely at any time.

“Highly automated driving” means that longitudinal guidance and lateral guidance of the motor vehicle are controlled automatically for a certain period of time in a specific situation (for example: driving on a highway, driving within a parking lot, overtaking an object, driving within a lane that is defined by lane markings). A driver of the motor vehicle does not have to control the longitudinal guidance and lateral guidance of the motor vehicle himself/herself manually. The driver does not have to monitor the automatic control of the longitudinal guidance and lateral guidance permanently, in order to be able to intervene manually if necessary. If necessary, a prompt to take over the control of the longitudinal guidance and lateral guidance is output to the driver automatically, in particular with a sufficient time-reserve. Accordingly, the driver has to be potentially capable of taking over the control of the longitudinal guidance and lateral guidance. Limits of the automatic control of the lateral guidance and longitudinal guidance are recognized automatically. In the case of highly automated driving, it is not possible to give rise to a minimal-risk state automatically in every initial situation.

“Fully automated driving” means that longitudinal guidance and lateral guidance of the motor vehicle are controlled automatically in a specific situation (for example: driving on a freeway, driving within a parking lot, overtaking an object, driving within a lane that is defined by lane markings). A driver of the motor vehicle does not have to control the longitudinal guidance and lateral guidance of the motor vehicle himself/herself manually. The driver does not have to monitor the automatic control of the longitudinal guidance and lateral guidance, in order to be able to intervene manually if necessary. Prior to a termination of the automatic control of the lateral guidance and longitudinal guidance, a prompt is given to the driver automatically to take over the driving task (control of the lateral guidance and longitudinal guidance of the motor vehicle), in particular with a sufficient time-reserve. If the driver does not take over the driving task, the system is returned automatically to a minimal-risk state. Limits of the automatic control of the lateral guidance and longitudinal guidance are recognized automatically. In all situations, it is possible to revert automatically to a minimal-risk system state.

The wording “at least one” encompasses the wording “one or more.”

Environment sensorics in the sense of the description-that is to say, in particular, the environment sensorics of the motor vehicle and/or the environment sensorics of the infrastructure—comprise, for example, one or more environment sensors. The environment sensors of the environment sensorics of the infrastructure are, for example, arranged in spatially distributed manner within the infrastructure. The environment sensors of the environment sensorics of the motor vehicle are, for example, arranged on the motor vehicle in spatially distributed manner and/or have been integrated within the motor vehicle—that is to say, they are encompassed by the motor vehicle. An environment sensor in the sense of the description is, for example, one of the following environment sensors: radar sensor, lidar sensor, image sensor, in particular an image sensor of a video camera, magnetic-field sensor, infrared sensor, and ultrasonic sensor. The environment sensorics of the infrastructure may, for example, be designated as infrastructure environment sensorics. The environment sensorics of the motor vehicle may, for example, be designated as motor-vehicle environment sensorics.

Motor-vehicle-generated environmental data are accordingly generated, in particular, within the motor vehicle.

Infrastructure-generated environmental data are accordingly generated, in particular, within the infrastructure.

A data set in the sense of the description may, for example, also be designated as a test data set, to the extent that the data set can be used, in particular, for testing at least one component of a process chain for an at least partially automated driving function of a motor vehicle. Such a test data set can be used, in particular, for the method according to the third aspect.

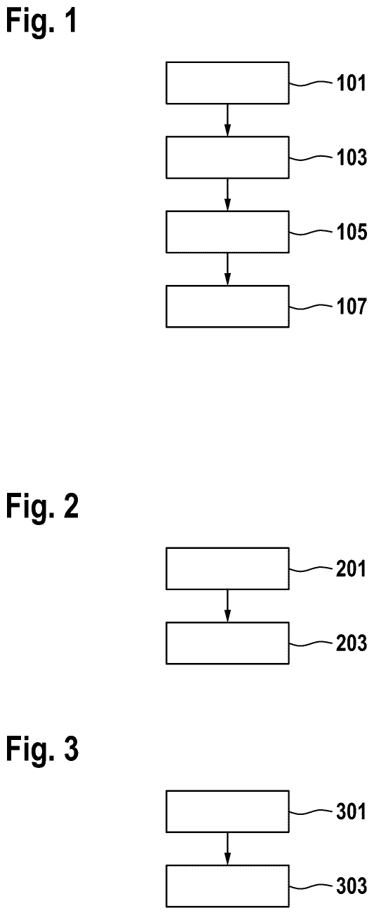

FIG. 1 shows a flowchart of a method for generating a data set, comprising the following steps:

receiving 101 motor-vehicle-generated environmental data that represent an environment of the motor vehicle from the perspective of the motor vehicle,

receiving 103 infrastructure-generated environmental data that represent the environment of the motor vehicle from the perspective of an infrastructure, editing 105 the motor-vehicle-generated environmental data on the basis of the

infrastructure-generated environmental data in order to ascertain edited motor-vehicle-generated environmental data, and

generating 107 a data set that comprises the edited motor-vehicle-generated environmental data.

According to one embodiment of the method according to the first aspect, there is provision to output the generated data set. According to one embodiment, the data set that is output is stored on a computer-readable storage medium. According to one embodiment, the outputting includes sending the generated data set via a communications network.

FIG. 2 shows a flowchart of a method for testing at least one component of a process chain for an at least partially automated driving function of a motor vehicle, comprising the following steps:

receiving 201 a data set that, with the use of infrastructure-generated environmental data that represent an environment of the motor vehicle from the perspective of an infrastructure, comprises edited motor-vehicle-generated environmental data that represent an environment of the motor vehicle from the perspective of the motor vehicle,

testing 203 the at least one component of the process chain on the basis of the data set.

FIG. 3 shows a flowchart of a method for generating at least one part of an algorithm for an at least partially automated driving function of a motor vehicle, comprising the following steps:

receiving 301 a data set that, with the use of infrastructure-generated environmental data that represent an environment of the motor vehicle from the perspective of an infrastructure, comprises edited motor-vehicle-generated environmental data that represent an environment of the motor vehicle from the perspective of the motor vehicle,

generating 303 at least one part of an algorithm for an at least partially automated driving function of a motor vehicle on the basis of the data set.

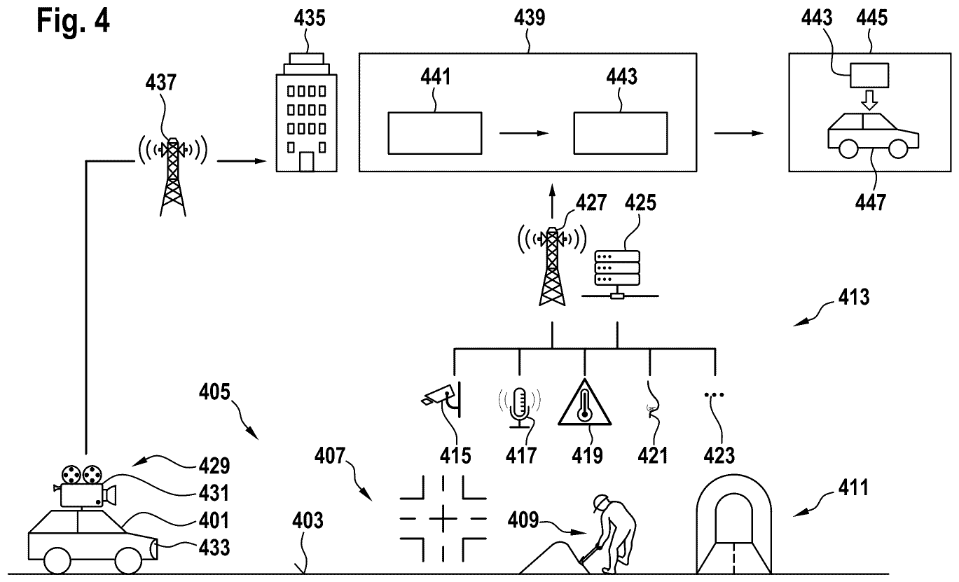

FIG. 4 shows a motor vehicle 401 during a journey, in particular during an at least partially automated journey, on a road 403 of an infrastructure 405. The infrastructure 405 may comprise, by way of example, one or more of the following infrastructure regions which have been represented by pictograms with appropriate reference symbols: intersection 407, construction site 409, tunnel 411. This means, in particular, that the road 403 may lead through one or more of the infrastructure regions 407, 409, 411 designated above.

Within the infrastructure 405, environment sensorics 413 are arranged that have been set up to monitor, on the infrastructure side, the road 403, for example, and an infrastructure region, for example, for instance one of the infrastructure regions 407, 409, 411. The environment sensorics 413 comprise, by way of example, a video camera 415, including an image sensor, a microphone 417, a temperature sensor 419, a gas sensor 421, characterized symbolically by a nose symbol. Furthermore, three dots are identified by reference symbol 423, this being intended to symbolize that the environment sensorics 413 may include further environment sensors.

The video camera 415, the microphone 417, the temperature sensor 419 and the gas sensor 421 are arranged in spatially distributed manner within the infrastructure 405. These environment sensors capture their respective environment and output environment-sensor data corresponding to the capture. The environment-sensor data are infrastructure-generated environmental data.

The environment-sensor data can be processed, for instance with the aid of a first computer system 425, in order to detect objects in the respective environment of the environment sensors. Upon detection of an object, information about the detected object—for instance, a position, a speed, and a direction of motion—can be sent to the motor vehicle 401, for example with the aid of a first wireless communications interface 427, in order to assist the motor vehicle in infrastructure-assisted manner in the course of its journey through the infrastructure 405.

The motor vehicle 401 includes environment sensorics 429 which exhibit a further video camera 431 exhibiting an image sensor, and also a radar sensor 433. These environment sensors capture an environment of the motor vehicle 403 and output environment-sensor data corresponding to the respective capture. The environment-sensor data are motor-vehicle-generated environmental data. The motor-vehicle-generated environmental data describe the environment of the motor vehicle 401 from the perspective of the motor vehicle 401.

The infrastructure-generated environmental data of the environment sensor(s) of the infrastructure 405 that captures/capture the environment of the motor vehicle 401 describe the environment of the motor vehicle 401 from the perspective of the infrastructure 405.

The motor vehicle 401 sends the motor-vehicle-generated environmental data via a wireless communications network—for instance, WLAN and/or mobile radiocommunications—to a computing center 435 which receives these environmental data with the aid of a second wireless communications interface 437. As an alternative to, or in addition to, the wireless transmission of the motor-vehicle-generated environmental data from the motor vehicle 401 to the computing center 435, a wired or cable-bound communication after the journey of the motor vehicle 401—that is to say, when it has arrived at a destination and been parked there—may have been provided, and/or these environmental data can be stored on a machine-readable storage medium, for instance a hard disk, in particular an SSD, in which case the machine-readable storage medium is sent to the computing center 435.

Arranged within the computing center 435 is a second computer system 439 which processes the motor-vehicle-generated environmental data. The processing includes editing the motor-vehicle-generated environmental data. For this editing, the second computer system 439 uses the infrastructure-generated environmental data that are sent from the first computer system 425 to the computing center with the aid of the first wireless communications interface 427.

The editing is characterized by a function block 441. As a result, a data set 443 is generated that comprises the edited motor-vehicle-generated environmental data. The data set 443 can be used, for example, for a simulation 445, according to which a further motor vehicle 447 is traveling in at least partially automated manner through the infrastructure 405. For this at least partially automated journey, use is made of an at least partially automated driving function which is performed by an algorithm. The algorithm may be generated for the first time or may be developed further, so that the correspondingly generated or further developed algorithm can be tested within the scope of the simulation.

Furthermore, the infrastructure-side environment sensorics 413, for example, and/or the motor-vehicle-side environment sensorics 429, for example, can be tested and/or developed further on the basis of the data set 443. The infrastructure-side environment sensorics 413 and the motor-vehicle-side environment sensorics 429 and also the algorithm are exemplary components of a process chain for an at least partially automated driving function of a motor vehicle.

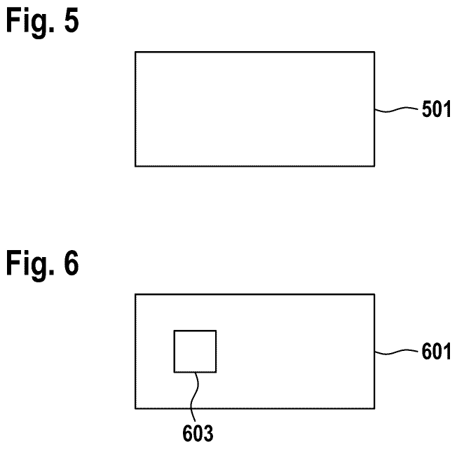

FIG. 5 shows a device 501 that has been set up to perform all the steps of the method according to the first aspect and/or according to the second aspect and/or according to the third aspect.

FIG. 6 shows a machine-readable storage medium 601 on which a computer program 603 has been stored. The machine-readable storage medium 601 is a non-transitory computer-readable medium. The computer program 603 includes commands that, upon execution of the computer program 603 by a computer, induce the latter to execute a method according to the first aspect and/or according to the second aspect and/or according to the third aspect.

In the known prior art, only information from the perspective of the motor vehicle is used for such testing or development of an algorithm. According to the prior art, what has occurred outside the region that is capable of being recognized by the environment sensorics of the motor vehicle is consequently not available. The concept described herein provides for using the perspective of the infrastructure of the respective traffic situation in addition to the perspective of the motor vehicle in order to edit the motor-vehicle-generated environmental data. A correspondingly generated data set can be used, for example, for developing motor-vehicle environment sensorics further.

For example, a costly and protracted further development of an algorithm or of an environment sensor can be avoided merely by a minor hardware modification—for instance, more visual range, for instance 1 degree more visual range, and/or more range, for instance 20 m more range—being provided, which could only result by virtue of the testing on the basis of the data set.

Through the use of the infrastructure-generated environmental data, the motor-vehicle-generated environmental data can be checked—for instance, validated—within the scope of the editing.

As a rule, no context of the current traffic situation is apparent from the motor-vehicle-generated environmental data. Such a context comprises, for instance:

traffic-control data (for instance, a traffic-light system changes its status (signal indication), lanes are closed, speed specifications are amended, dynamic traffic signs change their display, . . . ) and/or

an event influencing the environment, for example the fact that an ambulance is approaching from a distance and the road-users behave appropriately and make room, which would be strange behavior without the knowledge of the approaching ambulance, and/or

road-condition data and/or construction-site data and/or weather data.

Environmental data in the sense of the description comprise, for example, raw data—for example, images—and/or evaluated data—for example, object data from evaluated images.

In this way, a data set that is particularly suitable for generating and developing an algorithm for an at least partially automated driving function of a motor vehicle can be generated in efficient manner. The motor-vehicle-generated environmental data can be validated automatically. That is, are these environmental data correct? Therefore, additional data (edited motor-vehicle-generated environmental data) can be made available to the algorithm. That is, the algorithm can be tested and/or validated against these data.

Therefore, a triggering algorithm for accepting the motor-vehicle-generated environmental data can, in addition, be verified or developed further.

Therefore, a component of a process chain for an at least partially automated driving function of a motor vehicle can be optimally and efficiently developed and improved. For example, an optimal range and/or an optimal visual field of an environment sensor can be ascertained.

What is claimed is:

1. A method, comprising:
receiving a motor-vehicle-generated environmental data that represent an environment of a motor vehicle from a perspective of the motor vehicle;
receiving an infrastructure-generated environmental data that represent the environment of the motor vehicle from a perspective of an infrastructure;
editing the motor-vehicle-generated environmental data based on the infrastructure-generated environmental data in order to ascertain an edited motor-vehicle-generated environmental data; and
generating a data set that comprises the edited motor-vehicle-generated environmental data.

2. The method of claim 1, wherein the editing includes validating the motor-vehicle-generated environmental data to ascertain a result of validation, so that the edited motor-vehicle-generated environmental data include the result of validation.

3. The method of claim 1, wherein the editing includes checking a plausibility of the motor-vehicle-generated environmental data in order to ascertain a result of checking the plausibility, so that the edited motor-vehicle-generated environmental data include the result of checking the plausibility.

4. The method of claim 1, wherein the editing includes purging the motor-vehicle-generated environmental data of a faulty data, so that the edited motor-vehicle-generated environmental data is a purged motor-vehicle-generated environmental data.

5. The method of claim 1, wherein the editing includes analyzing the infrastructure-generated environmental data to obtain an environmental information about the environment of the motor vehicle, the editing includes enriching the motor-vehicle-generated environmental data with the environmental information, so that the edited motor-vehicle-generated environmental data include the environmental information.

6. The method of claim 1, wherein the infrastructure-generated environmental data include a context data that represent a context of the environment, so that the motor-vehicle-generated environmental data are edited based on the context data.

7. The method of claim 6, wherein the context comprises one or more of the following contexts: a constructional context, a traffic context, an event context, a weather context, and a road-condition context.

8. The method of claim 1, wherein the motor-vehicle-generated environmental data are generated based on a capture of the environment with a plurality of environment sensorics of the motor vehicle, at least one technical parameter of the environment sensorics of the motor vehicle is received, the data set is generated to include the at least one technical parameter of the environment sensorics of the motor vehicle.

9. The method of claim 1, wherein the infrastructure-generated environmental data are generated based on a capture of the environment with a plurality of environment sensorics of the infrastructure, at least one technical parameter of the environment sensorics of the infrastructure is received, the data set is generated to include the at least one technical parameter of the environment sensorics of the infrastructure.

10. The method of claim 1, wherein the motor-vehicle-generated environmental data represent a respective environment of a plurality of motor vehicles from the perspective of the motor vehicles in the course of a respective journey through a respective infrastructure region of the infrastructure, the infrastructure-generated environmental data represent the respective environment of the motor vehicles from the perspective of the infrastructure.

11. The method of claim 10, wherein the respective infrastructure region is an element selected from the following group of infrastructure regions: a road interchange, a construction site, a tunnel, a freeway entrance ramp, a freeway exit ramp, a freeway, a stopping-point, an entry, an exit, a constriction, a road constriction, a lane constriction, an underpass, and a place with adjacent public traffic.

12. The method of claim 10, wherein at least some of the respective infrastructure regions are identical to one another and/or at least some of the infrastructure regions are different from one another.

13. The method of claim 1, wherein the data set is generated in such a manner that it comprises the motor-vehicle-generated environmental data and/or the infrastructure-generated environmental data.

14. A method for testing at least one component of a process chain for an at least partially automated driving function of a motor vehicle, comprising:
receiving a data set that, with use of an infrastructure-generated environmental data that represent an environment of the motor vehicle from a perspective of an infrastructure, includes an edited motor-vehicle-generated environmental data that represent the environment of the motor vehicle from the perspective of the motor vehicle; and
testing the at least one component of the process chain based on the data set.

15. The method of claim 14, wherein the at least one component includes an algorithm for performing the at least partially automated driving function, the testing includes simulating the motor vehicle that is traveling in the at least partially automated manner based on the at least partially automated driving function, executing the algorithm.

16. The method of claim 14, wherein a motor-vehicle-generated environmental data is generated based on a capture of the environment with a plurality of environment sensorics of the motor vehicle, the data set includes at least one technical parameter of the environment sensorics of the motor vehicle, the at least one component includes the environment sensorics of the motor vehicle, the testing includes changing the at least one technical parameter based on the data set, in order to obtain at least one changed technical parameter, and the testing includes simulating the motor vehicle, exhibiting a plurality of simulated environment sensorics with the at least one changed technical parameter, that is traveling in the at least partially automated manner based on the at least partially automated driving function, using the simulated environment sensorics.

17. A method for generating at least one part of an algorithm for an at least partially automated driving function of a motor vehicle, comprising:
receiving a data set that, with use of an infrastructure-generated environmental data that represent an environment of the motor vehicle from a perspective of an infrastructure, includes an edited motor-vehicle-generated environmental data that represent the environment of the motor vehicle from a perspective of the motor vehicle; and
generating the at least one part of the algorithm for the at least partially automated driving function of the motor vehicle based on the data set.

18. The method of claim 17, wherein the at least one part of the algorithm is generated by using an artificial neural network.

19. The method of claim 17, wherein the data set includes a motor-vehicle-generated environmental data and/or the infrastructure-generated environmental data.

20. The method of claim 17, wherein the data set is generated by:
receiving a motor-vehicle-generated environmental data that represent the environment of a motor vehicle from the perspective of the motor vehicle;
receiving the infrastructure-generated environmental data that represent the environment of the motor vehicle from the perspective of the infrastructure; and
editing the motor-vehicle-generated environmental data based on the infrastructure-generated environmental data in order to ascertain the edited motor-vehicle-generated environmental data
